(19) United States
(12) Patent Application Publication
(10) Pub. No.: US 2006/0266549 A1
(43) Pub. Date: Nov. 30, 2006

(54) Printed circuit board with differential vias arrangement

(75) Inventors: Yu-Hsu Lin, San Jose, CA (US); Shang-Tsang Yeh, Tu-Cheng (TW); Chuan-Bing Li, Shenzhen (CN)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: HON HAI Precision Industry CO., LTD., Tu-Cheng City (TW)

(21) Appl. No.: 11/389,960

(22) Filed: Mar. 27, 2006

(30) Foreign Application Priority Data
May 28, 2005 (CN) 200510034951.1

(51) Int. Cl. H05K 7/06

(52) U.S. Cl. 174/262; 29/846

(57) ABSTRACT

A printed circuit board (PCB) with crosstalk reduction arrangement of differential vias includes a plurality of groups of differential vias, a plurality of signal lines corresponding to the differential vias, and a plurality of layers electrically connected with each other by the differential vias and signal lines. Each group of differential vias comprises a first pair of differential vias and a second pair of differential vias. Straight lines from a center of one of the first pair of vias to a center of another of the first pair of vias and from a center of one of the second pair of differential vias to a center of another of the second pair of differential vias are mutually perpendicularly bisecting.

### BACKGROUND OF THE INVENTION

1. Field of the Invention

The present invention relates to a printed circuit board (PCB), and more particularly to a PCB with crosstalk reduction arrangement of differential vias.

2. General Background

With the rapid improvement in speed of switches in integrated circuits (ICs) and the increasing density of signal lines of a PCB, demand for better quality transmission characteristics of signal lines is growing.

However, due to the increasing density of the signal lines, crosstalk between signal lines produced by electromagnetic coupling of the different signal lines is a growing design problem. A great amount of crosstalk produces electromagnetic noise that can influence performance of a computer system, and sometimes even can cause computer failure. So crosstalk is an important consideration in the PCB process.

Typically, differential pair lines are a pair of signal lines that are used to transmit differential signals of a PCB. The differential pair lines are used to eliminate the crosstalk and improve the transmission characteristics of signal lines because they transmit two equivalent, inverting differential signals at the same time. Therefore, designing of differential pair lines is important for PCB designing.

More signal transmission layers are needed because of the increasing density of signal lines. So it is inevitable that signal transmissions between different layers of a PCB should be achieved through conductive vias. Design of the conductive vias is crucial in the design of multilayer PCBs. The vias can be divided into three types according to their usage and process of manufacture. They are blind vias, buried vias, and through vias. The blind vias are usually located on a surface of the top layer or bottom layer of the PCB to conduct signals between surface layers and inner layers. The buried vias are located in the inner layers, and the through vias penetrate through all the layers of the PCB to complete electrical connections among all the layers. The through vias can also be used as tooling holes to rivet components to the PCB. When a connection between the vias and differential transmission lines is necessary, the differential vias are produced in pairs to connect with the differential pair lines. When current is input to transmission lines, a corresponding electromagnetic field is produced around the lines. Then the parasitic capacitances and the parasitic inductances of the differential vias interconnect with the electromagnetic field, and the interconnection causes crosstalk that affects the transmission quality of the signals.

Referring to FIG. 3, a typical differential vias arrangement on a portion of a PCB is shown. The PCB includes ground holes (not shown) amongst the differential vias though they are not a factor in this topic. The differential vias include a first pair of differential vias and a second pair of differential vias. The first pair of differential vias include a via 12 and a via 14. The second pair of differential vias include a via 22 and a via 24. Each via of the first pair and the second pair of differential vias are so arranged as to respectively occupy the corners of a rectangle with a side connecting vias of one pair parallel to a side connecting the other pair of vias. For example, when differential transmission lines 210(+) and 210(−) transmit differential signals through the vias 22 and 24 of the second pair of differential vias, crosstalk occurs. The crosstalk comes about due to a difference in the distance between a via of one pair to each of the vias in the other pair. Thus, the quality of the signal transmission characteristics is badly affected. Although reducing space between the differential vias can be useful for improving the problem, the cost and difficulties of the manufacturing process will be increased as well.

What is needed, therefore, is a PCB with a crosstalk reduction arrangement of differential vias.

### SUMMARY

An exemplary printed circuit board with crosstalk reduction arrangement of differential vias includes at least one group of differential vias, a plurality of signal lines corresponding to the differential vias, and a plurality of layers electrically connected with each other by the differential vias and the signal lines. Each group of differential vias comprises a first pair of differential vias and a second pair of differential vias. Straight lines from a center of one of the first pair of vias to a center of another of the first pair of vias and from a center of one of the second pair of differential vias to a center of another of the second pair of differential vias are mutually perpendicularly bisecting.

Other advantages and novel features will become more apparent from the following detailed description when taken in conjunction with the accompanying drawings, in which:

### BRIEF DESCRIPTION OF THE DRAWINGS

FIG. 1 is a schematic view of an arrangement of differential vias of part of a PCB in accordance with a preferred embodiment of the present invention;

FIG. 2 is a schematic view of an arrangement of differential vias of part of a PCB in accordance with another preferred embodiment of the present invention; and

FIG. 3 is a schematic view of an arrangement of differential vias of part of a typical PCB.

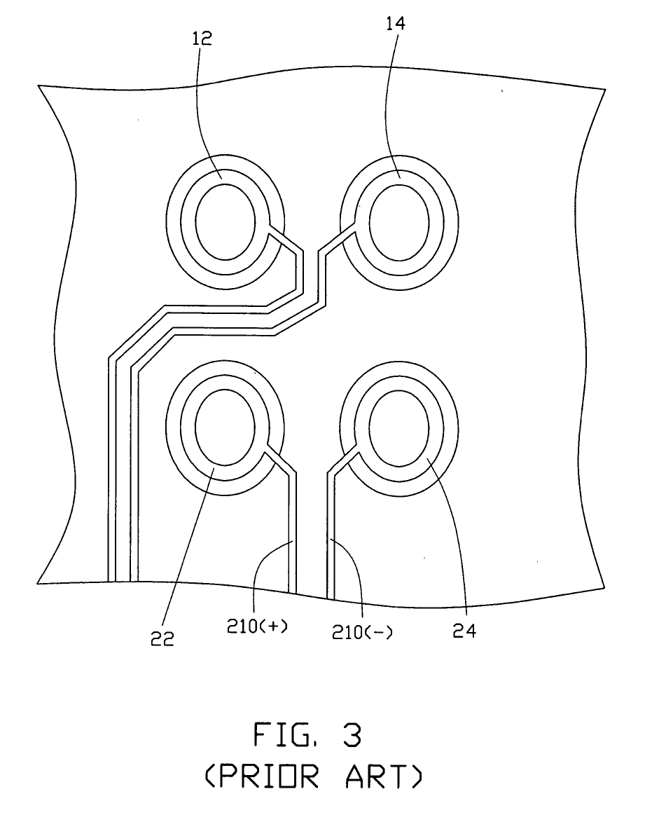

### DETAILED DESCRIPTION OF THE EMBODIMENTS

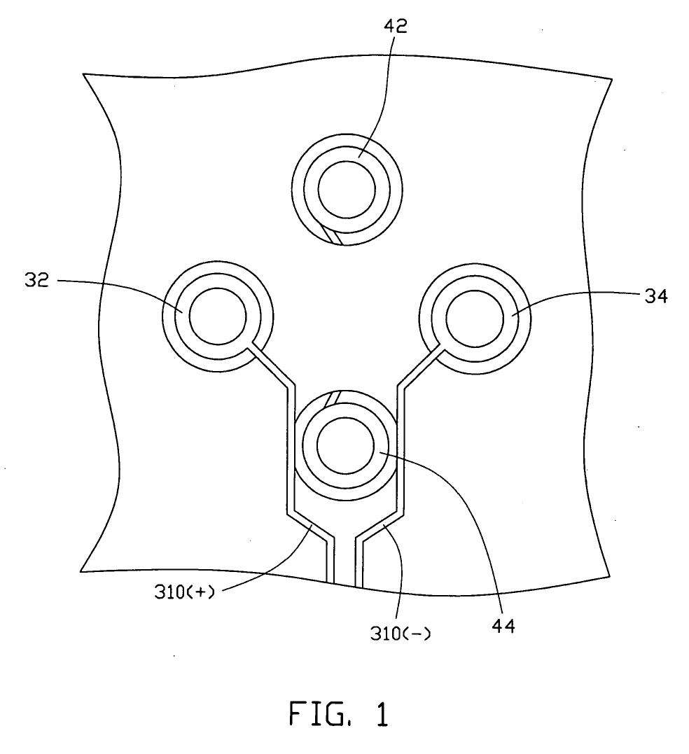

APCB with a crosstalk reduction arrangement of differential vias in accordance with the present invention comprises a plurality of groups of differential vias. Referring to FIG. 1, a single group of differential vias in accordance with a preferred embodiment of the present invention includes a first pair of differential vias and a second pair of differential vias. The first pair of differential vias comprises a via 32 and a via 34. The second pair of differential vias comprises a via 42 and a via 44. The two vias in a same pair are the same type. The vias can be blind vias, buried vias, or through vias. Straight lines from a center of the via 32 to a center of the via 34 and from a center of the via 42 to a center of the via 44 are mutually perpendicularly bisecting. That is to say that the vias 32, 34, 42, 44 are arranged in the shape of an imaginary rhombus including a square, and each of them respectively occupies a corner of the rhombus wherein all sides of the rhombus are equal and diagonal lines connecting the corners are mutually perpendicularly bisecting. Differential transmission lines 310(+) and 310(−) respectively connected to the vias 32, 34 of the first pair of differential vias are symmetrically located opposite each other along an axis of the vias 42, 44.

When the differential transmission lines 310(+) and 310(−) respectively transmit differential signals through the vias 32 and 34 of the first pair of differential vias, the crosstalk between the transmission lines is counteracted because they transmit two equivalent but inverted signals simultaneously when in use, thus any resulting crosstalk effects cancel each other. Potential crosstalk effects from the differential vias are mitigated in the following manner. Suppose the first pair of differential vias is a crosstalk disturbance source, and the second pair of differential vias is subject to that disturbance. When the differential transmission lines 310(+) and 310(−) transmit differential signals, the crosstalk is produced because of interactions of the two pair. To the via 44 of the second pair of differential vias, the arrangement of the vias 32 and 34 of the first pair of differential vias is equidistant and symmetrical. Therefore, a positive differential crosstalk and a negative differential crosstalk respectively caused by the via 32 and the via 34 are equivalent and inverted, and thus counteracted. Therefore, an expectant effect to reduce the crosstalk of the differential vias of the PCB is achieved.

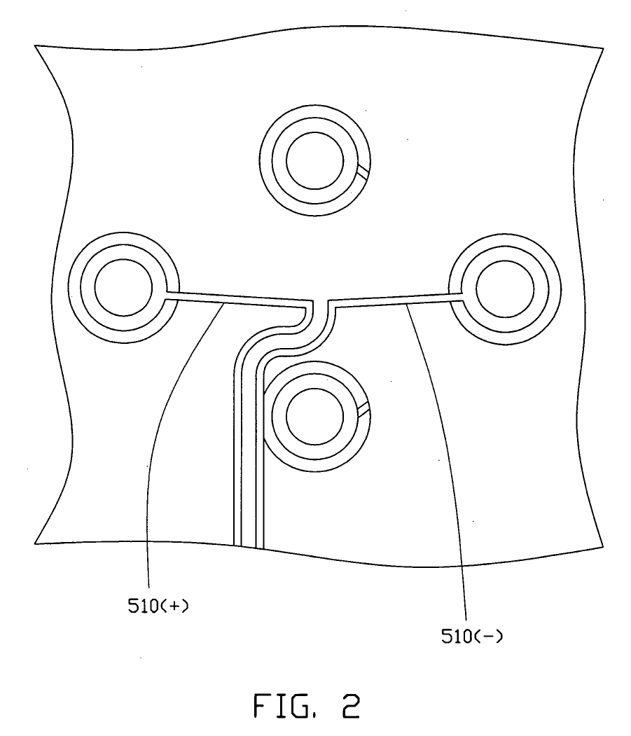

Referring to FIG. 2, a crosstalk reduction arrangement of differential vias of part of the PCB in accordance with another preferred embodiment of the present invention is shown. An arrangement of the differential vias of the FIG. 2 is analogous to that of the FIG. 1. The differences being that differential transmission lines 510(+) and 510(−) are not arranged symmetrically as in FIG. 1, and diagonal lines of the formed rhombus are not equal. However, arrangement of the two pairs of the differential vias of FIG. 2 is just another shape of the rhombus, therefore, an effect of the arrangement is the same as that of the first embodiment.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments.

What is claimed is:

1. A printed circuit board with crosstalk reduction arrangement of differential vias, the printed circuit board comprising:
at least one group of vias having a first pair of vias and a second pair of vias for transmitting differential signals, the pairs of vias being so arranged that straight lines from a center of one of the first pair of vias to a center of another of the first pair of vias and from a center of one of the second pair of differential vias to a center of another of the second pair of differential vias are mutually perpendicularly bisecting;
a plurality of transmission lines each connecting a corresponding via; and
a plurality of layers electrically connected with each other by the vias and the transmission lines.

2. The printed circuit board as claimed in claim 1, wherein the two vias in a same pair are the same type.

3. The printed circuit board as claimed in claim 2, wherein the two vias in a same pair are through vias.

4. The printed circuit board as claimed in claim 2, wherein the two vias in a same pair are blind vias.

5. The printed circuit board as claimed in claim 2, wherein the two vias in a same pair are buried vias.

6. A method for improving transmission characteristics of differential vias of a circuit board, comprising the steps of:
providing a circuit board;
setting a first pair of differential vias on said circuit board; and
setting a second pair of differential vias independent from said first pair on said circuit board, the pairs of vias being so arranged that a distance between a center of one of said first pair of differential vias and any one of said second pair of differential vias is equal to a distance between a center of the other one of said first pair of differential vias and any one of said second pair of differential vias.

7. The method as claimed in claim 6, wherein the two vias in a same pair are the same type.

8. The method as claimed in claim 7, wherein the two vias in a same pair are through vias.

9. The method as claimed in claim 7, wherein the two vias in a same pair are blind vias.

10. The method as claimed in claim 7, wherein the two vias in a same pair are buried vias.

11. A method for arranging circuitry of a circuit board, comprising the steps of:
forming a plurality of paired electrically transmissible vias in a circuit board;
arranging a first pair of said plurality of paired vias at a first location thereof in said circuit board; and
arranging a second pair of said plurality of paired vias at a second location thereof in said circuit board neighboring said first location so that each via of said second pair of said plurality of paired vias maintains equidistance from each via of said first pair of said plurality of paired vias.

12. The method as claimed in claim 11, wherein said each via of said first and second pairs of said plurality of paired vias occupies at a respective corner of a selective one of an imaginary square and an imaginary rhombus defined along said circuit board.
